(19) United States
(12) Patent Application Publication
(10) Pub. No.: US 2015/0276889 A1
(43) Pub. Date: Oct. 1, 2015

(54) ELECTROCHEMICAL ANALYSIS APPARATUS AND ELECTROCHEMICAL SYSTEM

(71) Applicant: WASEDA UNIVERSITY, Tokyo (JP)

(72) Inventors: Tetsuya OSAKA, Tokyo (JP); Toshiyuki MOMMA, Tokyo (JP); Tokihiko YOKOSHIMA, Tokyo (JP); Daikichi MUKOYAMA, Tokyo (JP); Hiroki NARA, Tokyo (JP)

(73) Assignee: WASEDA UNIVERSITY, Tokyo (JP)

(21) Appl. No.: 14/671,200

(22) Filed: Mar. 27, 2015

(30) Foreign Application Priority Data
Mar. 28, 2014 (JP) 2014-069693

(51) Int. Cl. G01R 31/36

(52) U.S. Cl. CPC G01R 31/3662; G01R 31/3606; G01R 31/3648

(57) ABSTRACT

An electrochemical analysis apparatus includes a power controller, a Fourier transform unit, and a calculating unit. The power controller generates a rectangular-wave signal, a first frequency F and a duty ratio D, and applies the signal to an electrochemical cell. The Fourier transform unit performs Fourier transform on first data obtained by sampling a response signal of the cell to calculate a first frequency characteristic including a component of a second frequency integer times as high as the first frequency. The Fourier transform unit performs Fourier transform on second data, a sampling start time of which is (1/F)·D (seconds) different from the first data from which the first frequency characteristic is calculated, to calculate a second frequency characteristic including a component of the second frequency. The calculating unit calculates an impedance characteristic of the cell based on the first frequency characteristic and the second frequency characteristic.

### CROSS REFERENCE TO RELATED APPLICATION

This application is based upon and claims priority from Japanese Patent Application No. 2014-069693 filed in Japan on Mar. 28, 2014, the entire contents of which are incorporated herein by reference.

### BACKGROUND OF THE INVENTION

1. Field of the Invention

Embodiments of the present invention relate to an electrochemical analysis apparatus that measures a characteristic of an electrochemical cell including a plurality of electrodes and an electrolyte and an electrochemical system including the electrochemical analysis apparatus.

2. Description of the Related Art

Impedance measurement of an electrochemical cell including a plurality of electrodes and an electrolyte is widely used for, for example, clarification of a mechanism of an electrochemical reaction. As an impedance measurement method, an alternating-current impedance method is known, which scans a frequency of a sine wave signal applied to a measurement-target electrochemical cell.

In the alternating-current impedance method, a frequency response analyzer (FRA) and a potentiostat are used. The FRA outputs a frequency response signal for applying a sine wave signal having a predetermined frequency to an electrochemical cell. The potentiostat controls, based on the frequency signal from the FRA, a voltage (an electric current) applied to the electrochemical cell.

By scanning the frequency of the sine wave signal, impedances at a plurality of frequencies, that is, frequency characteristics of the impedances are acquired. A track of the impedances obtained by representing the frequency characteristics of the impedances in a complex plan view in which a Z′ (real number impedance) axis indicates a resistance component and a Z″ (imaginary number impedance) axis indicates a reactance component (usually, capacitive) is a Nyquist plot (a Cole-Cole plot).

A Nyquist plot shown in FIG. 1 is a Nyquist plot in the case of a simple model that takes into account electrolyte resistance R_{S}, interface resistance Rᵢₙₜ consisting of charge transfer resistance, film resistance, and the like, a capacity C of an electric double layer or the like incidental to the electrolyte resistance R_{S} and the interface resistance Rᵢₙₜ, and diffusion Z_{W} of a charge carrier. That is, an electrochemical reaction of a simple system in an electrochemical cell including a reference electrode is formed by movement of ions in an electrolyte, a charge transfer reaction on an electrode interface, and diffusion of ions involved in the movement of the ions and the charge transfer reaction. Note that, in an electrochemical cell not including a reference electrode, impedances of two electrodes (a positive electrode and a negative electrode) are included. Therefore, a track of a semicircle is a track on which at least two semicircles overlap. By analyzing the track using an appropriate equivalent circuit mode, it is possible to grasp a characteristic of each of components such as the plurality of electrodes and the electrolyte that configure the electrochemical cell.

For example, when the diameter of the semicircle indicating the interface resistance Rᵢₙₜ increases, this indicates that a change has occurred in the electrochemical cell. That is, in a secondary battery, this indicates that the battery is deteriorated. When the electrochemical cell is a lithium ion battery, it is surmised that resistance increases because of deterioration of an active substance itself such as a change in a crystal structure and because a lithium ion electrolyte component and an organic solvent in the electrolyte decompose and deposit in forms of an organic substance and an inorganic substance on the surfaces of the negative electrode and the positive electrode as an electrolyte decomposition product and insertion and removal of lithium ions is hindered.

An electric vehicle or the like, which has been spread in recent years, includes a secondary battery, which is an electrochemical cell, as a power source. However, because of high costs, it is unrealistic to mount a frequency response analyzer and a potentiostat in each automobile in order to evaluate a characteristic with the alternating-current impedance method.

To realize a low carbon society, introduction of renewable energy such as solar power generation or wind power generation is ongoing. In order to perform stable power supply using the renewable energy, a large power storage system is indispensable.

The large power storage system includes a large-capacity secondary battery as a main component. The internal resistance of the large-capacity secondary battery is extremely low. Therefore, in order to evaluate a characteristic with the alternating-current impedance method, an extremely expensive large-capacity potentiostat is necessary. For example, when the internal resistance of the secondary battery is 10 mΩ, 300 A is necessary as a signal current of the potentiostat for controlling a voltage to 3 V. When the internal resistance is 1 mΩ, 3000 A is necessary as the signal current. The voltage control is not easy.

Note that Japanese Patent Application Laid-Open Publication No. 2003-090869 discloses a measurement apparatus that applies a signal obtained by superimposing sine waves having a plurality of frequencies to a battery and subjecting a response signal to Fourier transform to acquire impedances at the plurality of frequencies.

Japanese Patent Application Laid-Open Publication No. 2012-185167 discloses that, in a power storage apparatus including a plurality of batteries, a pseudo sine wave signal is applied from one battery to the other batteries to measure impedance.

### SUMMARY OF THE INVENTION

An electrochemical analysis apparatus in an embodiment of the present invention includes: a power controller that generates a rectangular wave signal, a frequency of which is a first frequency F and a duty ratio of which is D, and applies the rectangular wave signal to an electrochemical cell including a plurality of electrodes and an electrolyte; a Fourier transform unit that subjects first data obtained by sampling a response signal of the electrochemical cell to the rectangular wave signal for (1/F) second to Fourier transform and calculates a first frequency characteristic including a component of a second frequency, which is integer times as high as the first frequency, and subjects second data, a sampling start time of which is (1/F)×D (seconds) different from the first data from which the first frequency characteristic is calculated, to the Fourier transform and calculates a second frequency characteristic including a component of the second frequency integer times as high as the first frequency; and a calculating unit that calculates an impedance characteristic of the electrochemical cell based on the first frequency characteristic and the second frequency characteristic.

An electrochemical system in another embodiment of the present invention includes: an electrochemical analysis apparatus including: a power controller that generates a rectangular wave signal, a frequency of which is a first frequency F and a duty ratio of which is D, and applies the rectangular wave signal to an electrochemical cell including a plurality of electrodes and an electrolyte; a Fourier transform unit that subjects first data obtained by sampling a response signal of the electrochemical cell to the rectangular wave signal for (1/F) second to Fourier transform and calculates a first frequency characteristic including a component of a second frequency, which is integer times as high as the first frequency, and subjects second data, a sampling start time of which is (1/F)×D (seconds) different from the data from which the first frequency characteristic is calculated, to the Fourier transform and calculates a second frequency characteristic including a component of the second frequency integer times as high as the first frequency; and a calculating unit that calculates an impedance characteristic of the electrochemical cell based on the first frequency characteristic and the second frequency characteristic; and the electrochemical cell.

### BRIEF DESCRIPTION OF THE DRAWINGS

FIG. 1 is a diagram showing an example of a Nyquist plot;

FIG. 2 is a configuration diagram of electrochemical systems in a first embodiment and a reference example;

FIG. 3A is a diagram for explaining a method of calculating impedance of an electrochemical analysis apparatus in the reference example;

FIG. 3B is a diagram for explaining a method of calculating impedance of the electrochemical analysis apparatus in the reference example;

FIG. 4 is a diagram showing a Nyquist plot by the electrochemical analysis apparatus in the reference example;

FIG. 5 is an example of input output data acquired by the electrochemical analysis apparatus;

FIG. 6A is a diagram of a method of calculating impedance of an electrochemical analysis apparatus in the first embodiment;

FIG. 6B is a diagram of a method of calculating impedance of the electrochemical analysis apparatus in the first embodiment;

FIG. 7 is a diagram showing a Nyquist plot in the electrochemical analysis apparatus in the first embodiment;

FIG. 8A is a diagram showing a battery unit of the electrochemical system in the first embodiment;

FIG. 8B is a diagram showing a battery unit of the electrochemical system in the first embodiment;

FIG. 8C is a diagram showing a battery unit of the electrochemical system in the first embodiment;

FIG. 9 is a diagram showing a Nyquist plot of an electrochemical system in a modification 1 of the first embodiment; and

FIG. 10 is a configuration diagram of an electrochemical system in a modification 2 of the first embodiment.

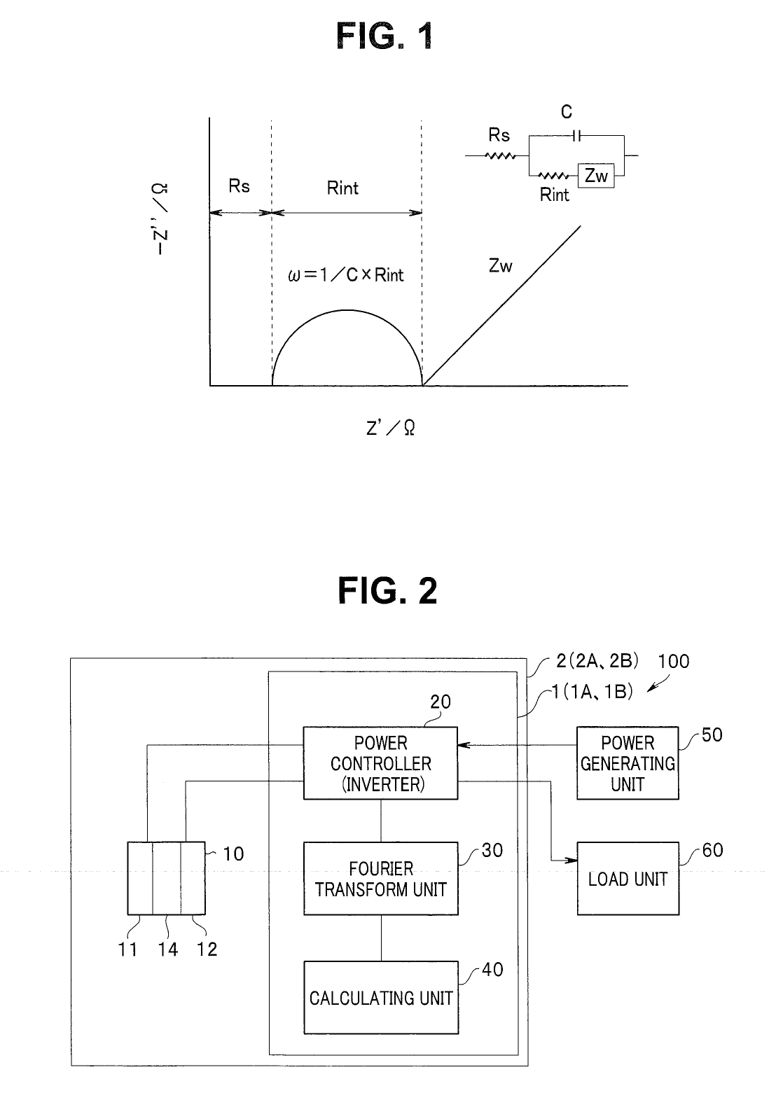

### DETAILED DESCRIPTION OF THE PREFERRED EMBODIMENTS

### Reference Example

For convenience of explanation, first, an electrochemical system 2 in a reference example is explained.

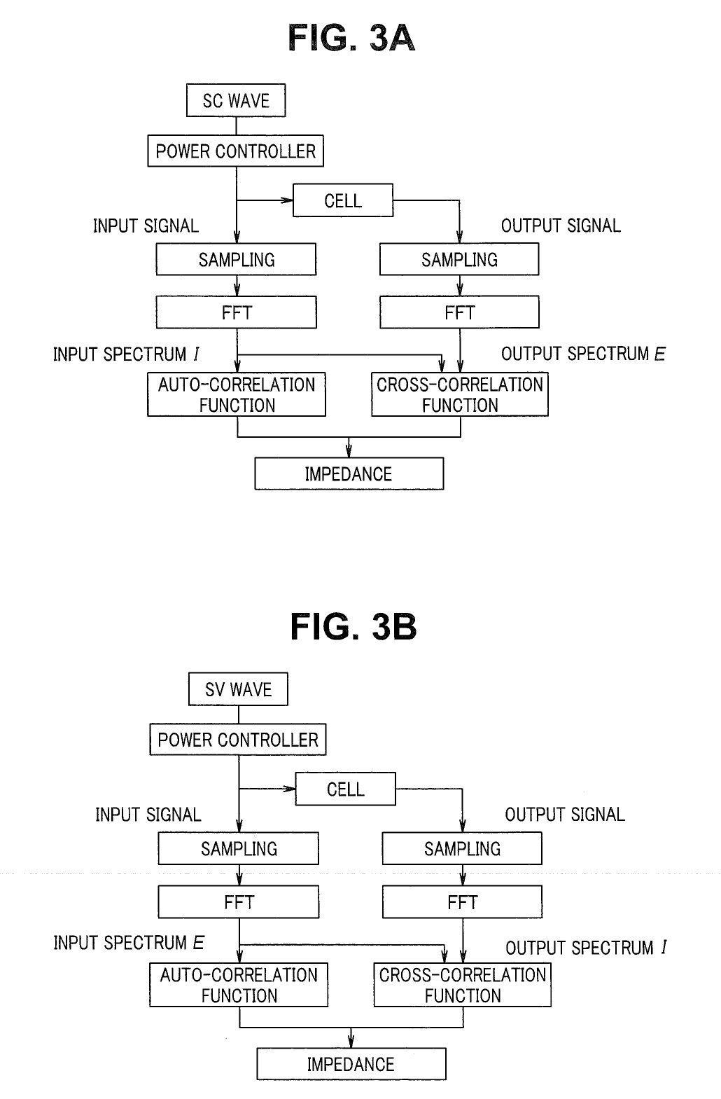

As shown in FIG. 2, the electrochemical system 2 in the reference example includes an electrochemical cell 10 and an electrochemical analysis apparatus 1. The electrochemical analysis apparatus 1 includes a power controller 20 that generates a signal applied to the electrochemical cell 10, a Fourier transform unit 30, and a calculating unit 40.

In the electrochemical system 2, the electrochemical cell 10 is a large-capacity secondary battery (hereinafter referred to as “battery”) and the power controller 20 is called inverter by those skilled in the art.

The battery is, for example, a lithium ion battery including a positive electrode 11 containing a lithium cobalt oxide or the like, a negative electrode 12 containing a carbon material or the like, and an electrolyte 14 obtained by dissolving LiPF₆ in annular and chain carbonate. Note that the electrochemical cell 10 may be a power storing unit that can temporarily store electricity.

The power controller 20 applies a voltage-controlled rectangular wave to the positive electrode 11 and the negative electrode 12 of the battery. The power controller 20 may apply a current-controlled rectangular wave. The power controller 20, which outputs a simple rectangular wave signal, may be configured by, for example, simply combining an ON/OFF switch, which operates at a predetermined cycle, to a direct-current power supply.

The Fourier transform unit 30 is an arithmetic circuit that subjects a rectangular wave signal applied by the power controller 20 and a response signal of the electrochemical cell 10 to the rectangular wave signal to Fourier transform and calculates frequency characteristics (spectra of an input signal and an output signal) including components of a second frequency (3f1, 5f1, 7f1, or the like) odd-number times as high as a first frequency (f1). The calculating unit 40 is an arithmetic circuit that calculates impedance characteristics including impedances and phase differences at a plurality of frequencies of the electrochemical cell 10 based on the input and output spectra calculated by the Fourier transform unit 30.

The Fourier transform unit 30 and the calculating unit 40 may be an integrated circuit, for example, a central processing unit (CPU) that performs control of the entire electrochemical system 2.

The electrochemical system 2 is a large power storage system of a power system 100. In the power system 100, when a generated power amount from a power generating unit 50 such as a wind power generation unit or a solar power generation unit is insufficient for a power consumption amount of a load unit 60 such as a factory or a home, electric power is supplied from the battery 10 of the electrochemical system 2 to the load unit 60. On the other hand, when the generated power amount exceeds the power consumption amount, the battery 10 is charged.

Note that, when the electrochemical system 2 is a power storage system of an electric vehicle, a motor is the power generating unit 50 and the load unit 60. That is, when electric power is supplied, the motor is driven and power generation is performed using rotation of the motor.

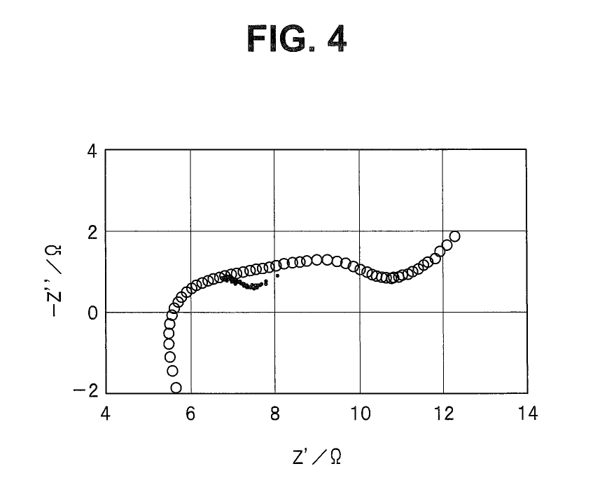

FIG. 3A is a flowchart for calculating impedances (Z′, Z″) at frequencies in the calculating unit 40 when a current rectangular wave (an SC wave) is used. A predetermined rectangular wave signal is applied to the electrochemical cell 10 using the power controller 20. An input signal current and an output signal voltage are sampled. The Fourier transform unit 30 subjects obtained data to the Fourier transform and obtains an input spectrum I and an output spectrum E. The calculating unit 40 calculates the impedances (Z′, Z″) at the respective frequencies from a cross-correlation function and an auto-correlation function of the spectra at that point according to the cross-correlation function/the auto-correlation function.

Note that the Fourier transform unit 30 and the calculating unit 40 processes an input signal and an output signal.

FIG. 3B is a flowchart for calculating the impedances (Z′, Z″) at the frequencies in the calculating unit 40 when a voltage rectangular wave (an SV wave) is used. A created rectangular wave signal is applied to the electrochemical cell 10 using the power controller 20 and an input signal voltage and an output signal current are sampled. The Fourier transform unit 30 subjects obtained data to the Fourier transform to obtain an input spectrum E and an output spectrum I. The calculating unit 40 calculates the impedances (Z′, Z″) at the respective frequencies from a cross-correlation function and an auto-correlation function of the spectra at that point according to the auto-correlation function/the cross-correlation function.

Note that the same result is obtained when the current rectangular wave (the SC wave) and when the voltage rectangular wave (the SV wave).

A pattern of the rectangular wave signal outputted by the power controller 20 may be used instead of the rectangular wave signal applied by the power controller 20. A rectangular wave signal actually applied to the electrochemical cell 10 by a transmission path is different from the pattern of the rectangular wave signal. However, when accuracy is not requested, processing the input signal may be simplified to calculate an auto-correlation coefficient.

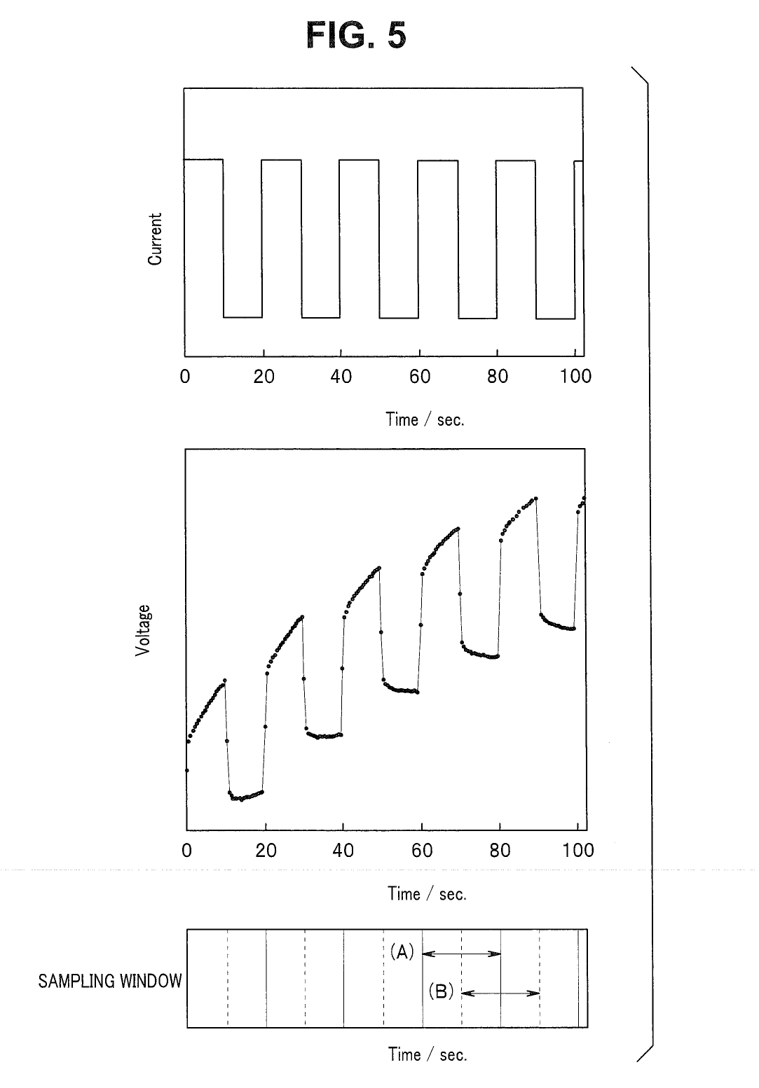

FIG. 4 is a Nyquist plot showing impedances (black dots) obtained by the electrochemical analysis apparatus 1 in the comparative example and impedances (white circles) calculated by the alternating-current impedance method.

Note that, in the electrochemical system 2 in the present embodiment, the power controller 20 applied a signal of a rectangular wave (an offset current=0.4 A, amplitude±0.4 A) at 50 mHz (ON 10 seconds/OFF 10 seconds: duty ratio D=1/2) to the battery 10. In the normal alternating-current impedance method, a frequency of a sine wave (an offset current=0.5 A, amplitude±0.5 A) was scanned from 100 kHz to 10 mHz using a frequency response analyzer and a large-capacity potentiostat. However, in a battery 10C, since internal resistance was extremely low at 10 mΩ, measurement by the normal alternating-current impedance method was not easy.

As shown in FIG. 4, the impedances calculated in the electrochemical system 2 in the reference example were greatly different from the impedances calculated by the alternating-current impedance method.

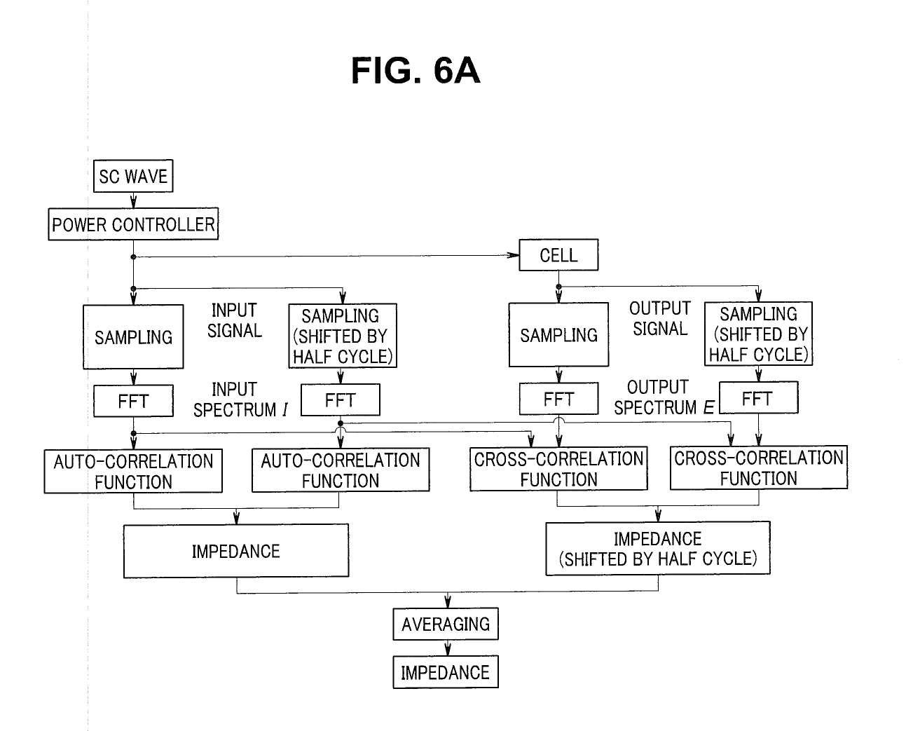

This is because, as shown in FIG. 5, a response voltage signal to a driving current wave changed. Since a sampling window (A) at a fourth application cycle started after 60 seconds from a measurement start was used in an analysis, the calculated impedances were greatly different from the impedances calculated by the alternating-current impedance method.

In the electrochemical system 2, if the rectangular wave application is continued for a long time, for example, one hour or more, the calculated impedances approach the impedances calculated by the alternating-current impedance method. This is because the response voltage signal to the driving current wave stabilizes.

As the frequency F of the rectangular wave is lower, time required for the stabilization of the impedances is longer. That is, when a rectangular wave in a low frequency region, in particular, in a mHz band in which a frequency was lower than 1 Hz was used, impedances did not stabilize in the beginning of measurement. In the electrochemical system 2, it was not easy to evaluate characteristics of the electrochemical cell 10 in a short time.

### First Embodiment

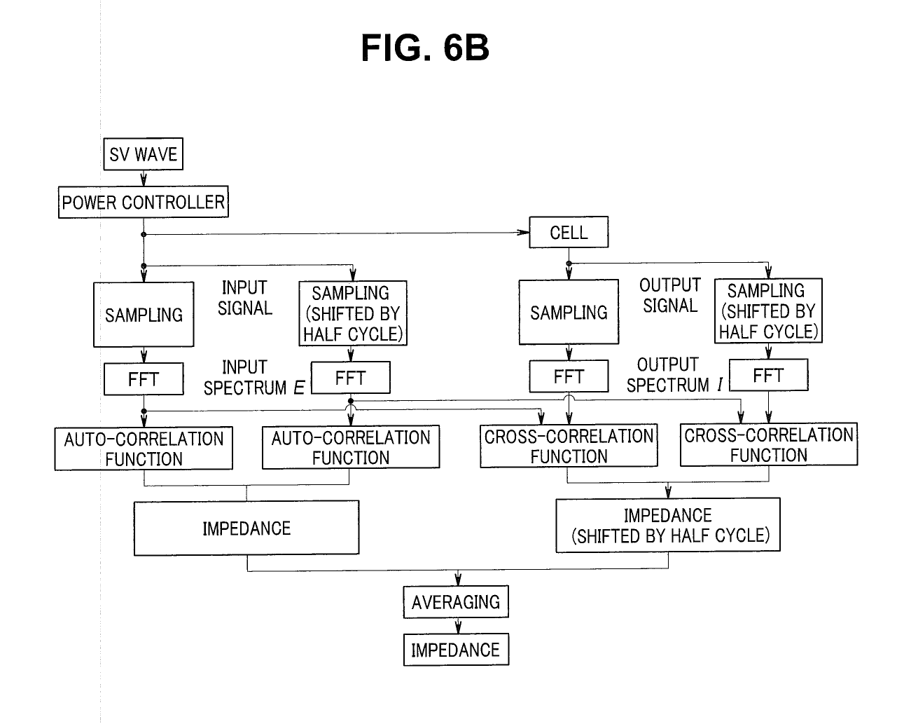

An electrochemical analysis apparatus 1A in a first embodiment of the present invention includes a configuration similar to the configuration of the electrochemical analysis apparatus 1 in the reference example. However, as shown in FIG. 6A, the Fourier transform unit 30 in the first embodiment not only subjects first data sampled by the sampling window (A) same as the sampling window (A) in the reference example to Fourier transform processing but also subjects second data sampled by a sampling window (B) shifted by a half cycle, that is, second data having a different sampling start time to the Fourier transform processing. When a duty ratio (TON/(TON+TOFF)) of a rectangular wave is D and a frequency of the rectangular wave is F, a time of the half cycle is (1/F)×D (seconds).

For example, in an example shown in FIG. 5, the rectangular wave has a frequency F=50 mHz (cycle: 20 seconds; ON 10 seconds/OFF 10 seconds: duty ratio, D=1/2). Therefore, the sampling window (B) of the second data opens 10 seconds (1/(5 mHz)×(1/2) later than the sampling window (A).

The calculating unit 40 calculates impedance characteristics respectively from two Fourier transform results and calculates an average of the calculated two impedance characteristics. In the calculation of the average, the impedances at the respective frequencies are added up and then divided by two.

Note that, instead of the current-controlled rectangular wave (SC wave), as shown in FIG. 6B, a voltage-controlled rectangular wave (SV wave) may be used as an input signal.

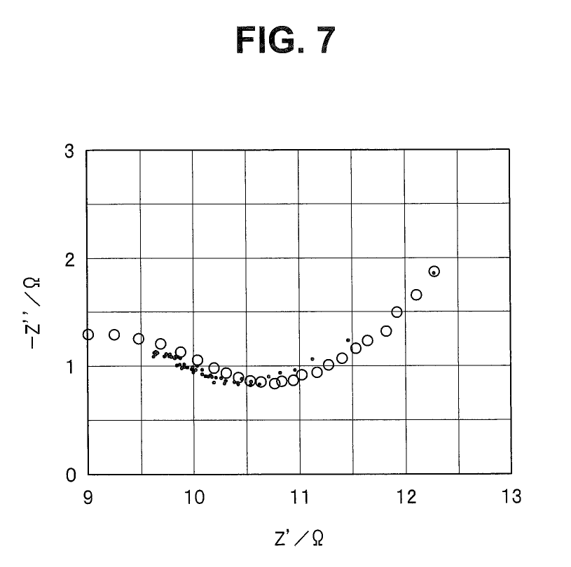

FIG. 7 is a Nyquist plot showing impedances (black dots) obtained by the electrochemical analysis apparatus 1A in the present embodiment and impedances (white circles) calculated by the alternating-current impedance method.

It is seen from FIG. 7, an impedance characteristic of the battery 10 acquired by the electrochemical analysis apparatus 1A coincides well with the impedances acquired by the alternating-current impedance method.

That is, in the electrochemical analysis apparatus 1A, by analyzing the data sampled by the two sampling windows (A) and (B) shifted by a half cycle, an impedance characteristic similar to the stable state that can be acquired after one hour in the electrochemical analysis apparatus 1 in the reference example was obtained.

In the present embodiment, in the rectangular wave, the frequency is F and the ON time (TON) and the OFF time (TOFF) are the same. In other words, duty ratio: D=TON/(TON+TOFF)=1/2. Therefore, the shifting by a half cycle means that the sampling is started (1/F)×(1/2) second earlier or later. Note that a sampling time is one cycle, that is, 1/F second.

Impedances having a higher frequency than the frequency F of the rectangular wave are acquired by the Fourier transform. Therefore, it is easily understood that a response signal is important when the rectangular wave is switched from a low level (a low current or a low voltage) to a high level (a high current or a high voltage) and when the rectangular wave is switched from the high level to the low level.

Therefore, if the timings of the sampling start of the two sampling windows are shifted by (duty ratio: D/Frequency F), it is possible to acquire a satisfactory impedance characteristic in a short time.

That is, the electrochemical analysis apparatus 1A in the present embodiment includes the power controller 20 that generates a rectangular wave signal, a frequency of which is a first frequency F1 and a duty ratio of which is D, and applies the rectangular wave signal to an electrochemical cell including a plurality of electrodes and an electrolyte, the Fourier transform unit 30 that subjects first data obtained by sampling a response signal of the electrochemical cell to the rectangular wave signal for a sampling time (1/F) or more second to Fourier transform and calculates a first frequency characteristic including a component of a second frequency, which is integer times as high as the first frequency, and subjects second data, a sampling start time of which is (1/F)×D (seconds) different from the data from which the first frequency characteristic is calculated, to the Fourier transform and calculates a second frequency characteristic including a component of the second frequency integer times as high as the first frequency, and the calculating unit 40 that calculates an impedance characteristic of the electrochemical cell based on the first frequency characteristic and the second frequency characteristic.

More specifically, the calculating unit 40 averages a first impedance characteristic of the electrochemical cell calculated based on the first frequency characteristic and a second impedance characteristic of the electrochemical cell calculated based on the second frequency characteristic and calculates an impedance characteristic of the electrochemical cell.

In the electrochemical analysis apparatus 1A in the embodiment, a rectangular wave signal having a duty ratio of 1/2 is generated. Therefore, a sampling start time is shifted by (1/F)×(1/2) (second).

Note that, if a sampling start was a third cycle (60 seconds) or later, a satisfactory result was obtained. That is, when the frequency F is mHz lower than 1 Hz with respect to the frequency F of the rectangular wave, it is preferable to start the sampling (3/F) seconds or later.

In the battery 10, internal resistance was extremely low at 10 mΩ. However, in the electrochemical analysis apparatus 1A, it was easy to acquire an impedance characteristic.

In the electrochemical system 2, even if the internal resistance of the battery is 10 mΩ or less, it is easy to acquire an impedance characteristic with the electrochemical analysis apparatus 1A. Further, even in a battery having internal resistance of 1 mΩ or less, for which measurement is extremely difficult by the normal alternating-current impedance method, it is easy to acquire an impedance characteristic with the electrochemical analysis apparatus 1A.

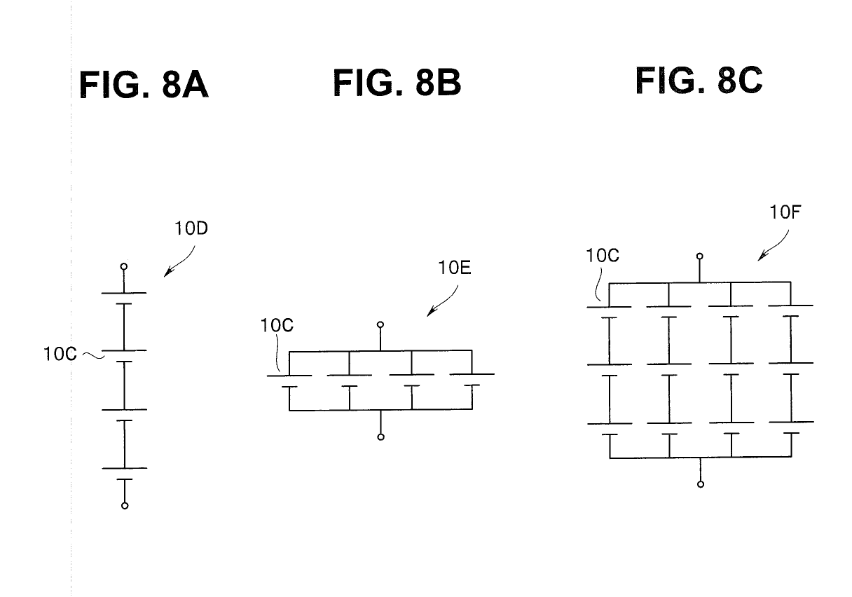

For simplification of explanation, the electrochemical system 2 includes one battery 10 as the electrochemical cell. However, even if the electrochemical cell is a battery unit 10D in which a plurality of batteries 10C are connected in series shown in FIG. 8A, a battery unit 10E in which the plurality of batteries 10C are connected in parallel shown in FIG. 8B, or a battery unit 10F in which the plurality of batteries 10C are connected in series and parallel shown in FIG. 8C, by applying a signal to the electrochemical cells, it is equally possible to detect a characteristic change of the entire battery unit 10E including the plurality of batteries 10C.

In particular, the internal resistance of the battery units 10E and 10F, in which the batteries are connected in parallel, is lower than the internal resistance of the respective batteries 10C. However, it is easy to acquire an impedance characteristic with the electrochemical analysis apparatus 1A.

As it is evident from the above results, although the electrochemical analysis apparatus 1A has a simple configuration not including a frequency response analyzer and a potentiostat, the electrochemical analysis apparatus 1A can acquire an impedance characteristic of the electrochemical cell 10 in the same manner as the alternating-current impedance method. By analyzing the acquired impedance characteristic using an equivalent circuit model, it is possible to grasp characteristics and the like of each of the components such as the electrodes and the electrolyte that configure the electrochemical cell 10.

Even if only a component of a second frequency (3f1) three times as high as at least one first frequency (f1) is obtained, that is, even in a Nyquist plot consisting of data at two points, an analysis is not impossible. Components of a plurality of second frequencies (f2) are preferably included and components of three or more second frequencies (f2) are particularly preferably included in input and output spectra calculated by the Fourier transform unit 30.

In order to stably obtain an impedance response based on the second frequency f2, measurement at a high sampling rate is preferable. As a sampling rate is higher, measurement of the high frequency f2 is easier. The sampling rate is preferably 100 times or more as high as the first frequency f1.

At the high frequency f1, noise tends to occur in a portion where positive and negative of an electric current inverse in the power controller 20. When noise occurs, it is preferable to offset a potential or current value to prevent positive and negative of the electric current from inversing.

That is, a direct-current power supply more inexpensive than an alternating-current power supply can be used for the power controller 20 of the electrochemical analysis apparatus 1A. Further, the power controller 20, which generates a direct-current rectangular wave, may be simply configured to only ON/OFF-control a signal of a predetermined potential or current value.

When the current value in the power controller 20 is near 0, the electric current sometimes shows a current waveform different from a current waveform in a region where a sufficient current value is obtained. In such a case, it is preferable to offset the potential or current value to prevent the electric current from decreasing to 0.

The input and output spectra calculated by the Fourier transform unit 30 include only the component of the frequency (3f1, etc.) odd number times as high as the first frequency (f1). On the other hand, if the first frequency (f1) is higher, a frequency (2f1, 4f1, or the like) integer times as high as the first frequency (f1) is sometimes included because of the influence of response speed of the cell 10.

That is, a component of a frequency integer times as high as the first frequency (f1) may be included in the input and output spectra calculated by the Fourier transform unit 30.

A rectangular wave signal outputted by the power controller 20 is not limited to a waveform having an extremely steep rising edge. The rectangular wave signal outputted by the power controller 20 is also regarded as a so-called saw-tooth wave that changes at a certain gradient when a frequency is increased. The rectangular wave signal outputted by the power controller 20 is not limited to a waveform having extremely steep rising and falling edges. The rectangular wave signal outputted by the power controller 20 is also regarded as a so-called triangular wave that changes at a certain gradient when a frequency is increased. That is, the rectangular wave in the present embodiment is a concept including the saw-tooth wave and the triangular wave.

Further, the rectangular wave signal outputted by the power controller 20 may be actively changed to a saw-tooth wave signal using a delay circuit such as an LC circuit.

In the saw-tooth wave, the triangular wave, and the like, a component of a frequency integer times as high as the first frequency (f1) is included in the input and output spectra calculated by the Fourier transform unit 30.

Further, the electrochemical cell is not limited to a lithium secondary battery. As the electrochemical cell, various secondary batteries and capacitors can be used as long as the secondary batteries and the capacitors are power storage devices that can store electricity.

### Modification 1 of the First Embodiment

In an electrochemical analysis apparatus 1B (an electrochemical system 2B) in the present modification, the power controller 20 applies a signal that is formed by a rectangular wave signal having the first frequency (f1) and has a second frequency (f3) lower than the first frequency (f1). The Fourier transform unit 30 calculates input and output spectra including a component of a third frequency (f3).

The Fourier transform unit 30 calculates input and output spectra including a component of the first frequency (f1) of the rectangular wave signal, a component of a frequency (3f1, 5f1, 7f1, or the like) odd number times as higher as the first frequency (f1), and a component of the third frequency (f3) lower than the first frequency (f1). Further, a component of a frequency odd number times as high as the second frequency (f3) is also included in the input and output spectra.

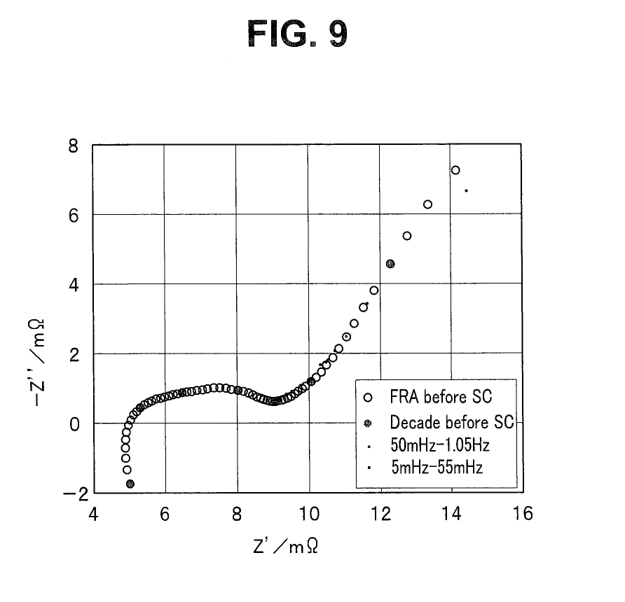

FIG. 9 shows a Nyquist plot in which an impedance characteristic acquired by the normal alternating-current impedance method is indicated by white circles and an impedance characteristic of the battery 10 acquired by the electrochemical analysis apparatus 1B is indicated by black dots.

Note that, in the electrochemical analysis apparatus 1B, the power controller 20 applied a rectangular wave signal (an offset current=0.6 A, amplitude±0.4 A) having the first frequency (f1) of 50 mHz to the battery 10. The power controller 20 applied a rectangular wave signal (an offset current=0.6 A, amplitude±0.4 A) having the third frequency (f1) of 5 mHz to the battery 10. In the normal alternating-current impedance method, a frequency of a sine wave (an offset current=0.5 A, amplitude±0.5 A) was scanned from 100 kHz to 10 mHz using a frequency response analyzer and a large-capacity potentiostat.

However, since the battery 10 has extremely low internal resistance of 10 mΩ, measurement by the normal alternating-current impedance method was not easy.

It is seen from FIG. 9 that an impedance characteristic of the battery 10 acquired by the electrochemical analysis apparatus 1B well coincides with an impedance characteristic acquired by the normal alternating-current impedance method. Although the battery 10 has extremely low internal resistance of 10 mΩ, acquisition of an impedance characteristic was easy in the electrochemical system 2.

### Modification 2 of the First Embodiment

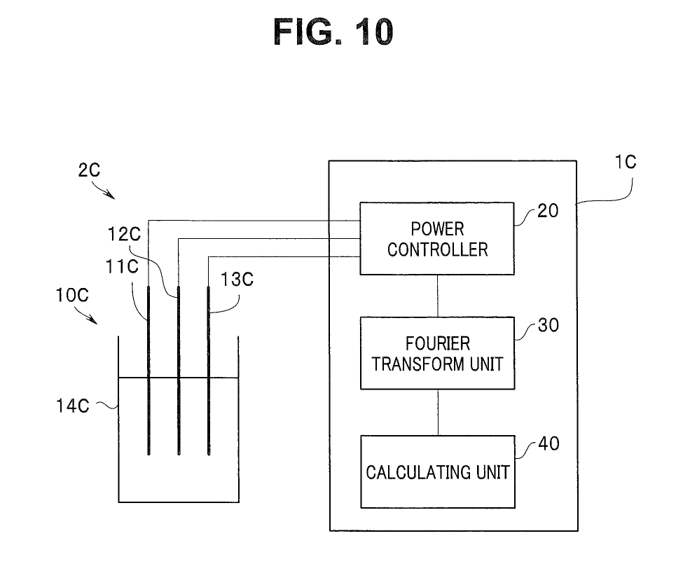

As shown in FIG. 10, an electrochemical system 2C in a modification 2 of the first embodiment includes an electrochemical cell 10C and an electrochemical analysis apparatus 1C. The electrochemical analysis apparatus 1C includes the power controller 20 that generates a signal applied to the electrochemical cell 10C, the Fourier transform unit 30, and the calculating unit 40. For example, in the electrochemical cell 10C, a working electrode (WE) 11C formed of glassy carbon, a counter electrode (CE) 12C formed of a platinum wire, a reference electrode (RE) 13C formed of silver/silver chloride and 3M-NaCl, and an electrolyte 14C containing a water solution including 5 mM of K₄[Fe(CN)₆], 5 mM of K₃[Fe(Cn)₆], and 0.5 M of KNO₃ can be used.

The power controller 20 generates a rectangular wave signal of a voltage having the first frequency f1 with reference to the reference electrode (RE) 13C and applies the rectangular wave signal to the working electrode (WE) 11C and the counter electrode (CE) 12C of the electrochemical cell 10C. A signal generated with reference to an electric current may be used instead of the voltage. The rectangular wave signal may be generated with reference to the counter electrode (CE) 12C without using the reference electrode (RE) 13C and applied to the working electrode (WE) 11C and the counter electrode (CE) 12C of the electrochemical cell 10C. The power controller 20 may apply a rectangular wave of an electric current. The power controller 20, which outputs a simple rectangular wave signal, may be configured by, for example, simply combining an ON/OFF switch, which operates at a predetermined cycle, with a direct-current power supply.

The present invention is not limited to the embodiments and the like explained above. Various changes and modifications, for example, combinations of the components in the embodiments are possible without departing from the spirit of the invention.

What is claimed is:

1. An electrochemical analysis apparatus comprising:
a power controller that generates a rectangular wave signal, a frequency of which is a first frequency F and a duty ratio (TON/(TON+TOFF)) of which is D, and applies the rectangular wave signal to an electrochemical cell including a plurality of electrodes and an electrolyte;
a Fourier transform unit that subjects first data obtained by sampling a response signal of the electrochemical cell to the rectangular wave signal for (1/F) second to Fourier transform and calculates a first frequency characteristic including a component of a second frequency, which is integer times as high as the first frequency, and subjects second data, a sampling start time of which is (1/F)×D (seconds) different from the data from which the first frequency characteristic is calculated, to the Fourier transform and calculates a second frequency characteristic including a component of the second frequency integer times as high as the first frequency; and
a calculating unit that calculates an impedance characteristic of the electrochemical cell based on the first frequency characteristic and the second frequency characteristic.

2. The electrochemical analysis apparatus according to claim 1, wherein
the duty ratio: D is 1/2, and
the sampling start time is (1/F)×(1/2) (seconds) different.

3. The electrochemical analysis apparatus according to claim 1, wherein the second frequency is a frequency odd number times as high as the first frequency.

4. The electrochemical analysis apparatus according to claim 3, wherein the first frequency is 1 Hz or less.

5. The electrochemical analysis apparatus according to claim 4, wherein
the power controller applies, to the electrochemical cell, a signal that is formed by rectangular wave signals having the first frequency in plurality and has a third frequency lower than the first frequency, and
the Fourier transform unit calculates a frequency characteristic including a component of the third frequency.

6. The electrochemical analysis apparatus according to claim 4, wherein
the power controller applies rectangular wave signals having a plurality of frequencies to the electrochemical cell, and
the Fourier transform unit calculates a frequency characteristic of a component of a frequency integer times as high as each of the plurality of frequencies.

7. The electrochemical analysis apparatus according to claim 6, wherein the plurality of frequencies of the rectangular wave signals are set such that frequencies odd number times as high as the frequencies are different.

8. The electrochemical analysis apparatus according to claim 1, wherein the electrochemical cell is a power storage device.

9. The electrochemical analysis apparatus according to claim 8, wherein the calculating unit further detects a characteristic change of the power storage device from the impedance characteristic.

10. The electrochemical analysis apparatus according to claim 9, wherein
the power controller applies the rectangular wave signal to a power storage unit including a plurality of power storage devices connected to one another, and
the calculating unit detects a characteristic change of the power storage unit.

11. The electrochemical analysis apparatus according to claim 9, wherein the power storage device is a secondary battery.

12. The electrochemical analysis apparatus according to claim 11, wherein internal resistance of the secondary battery is 10 mΩ or less.

13. The electrochemical analysis apparatus according to claim 1, wherein the rectangular wave signal generated by the power controller is a direct current.

14. An electrochemical system comprising:
the electrochemical analysis apparatus according to claim 1; and
the electrochemical cell.
